(19) United States
(12) Patent Application Publication
(10) Pub. No.: US 2013/0320777 A1
(43) Pub. Date: Dec. 5, 2013

(54) CONNECTOR DEVICE AND ELECTRONIC DEVICE

(71) Applicant: Fujitsu Limited, Kawasaki-shi (JP)

(72) Inventor: Akira NAKANISHI, Yokohama (JP)

(73) Assignee: Fujitsu Limited, Kawasaki-shi (JP)

(21) Appl. No.: 13/903,375

(22) Filed: May 28, 2013

(30) Foreign Application Priority Data
May 31, 2012 (JP) 2012-125058

(51) Int. Cl. H03K 17/94

(52) U.S. Cl. CPC H03K 17/94
USPC 307/130

(57) ABSTRACT

A connector device includes: a pin; a detector coupled to the pin and detects a voltage of the pin; a controller coupled to the detector and identifies that an external device is coupled to the pin on the basis of the voltage of the pin; and a switching circuit coupled to the pin and switches an output signal on the basis of a control signal output from the controller.

### CROSS-REFERENCE TO RELATED APPLICATION

This application is based upon and claims the benefit of priority of the prior Japanese Patent Application No. 2012-125058, filed on May 31, 2012, the entire contents of which are incorporated herein by reference.

### FIELD

The embodiments discussed herein are related to a connector device and an electronic device.

### BACKGROUND

Traditionally, as a connector device for an audio device, there has been a tripolar or tetrapolar jack interface. The jack interface is used for a mobile terminal or the like.

In the connector device, impedance of poles of left, right and middle channels of a plug connected to the jack interface is converted into voltages by a converting circuit. The converted voltages are compared with a standard voltage by first to third comparators, and first to third comparison results are output. A controller determines the type of an audio device connected to the jack interface on the basis of the first to third comparison results.

Aside from the conventional device that uses the jack interface, the U.S. CEA-936-A standard exists as a standard for connecting a terminal device such as a mobile phone terminal or a game machine to a head phone or a head set using micro-universal serial bus (micro-USB) connector. The head set includes speakers and a microphone and is used for a conversation on a phone or the like.

The micro-USB connector has five pins. The five pins are a power supply pin, an identification pin, two audio input and output pin for inputting and outputting audio signals and a ground (GND) pin.

Thus, in order to connect the head set to a device having a micro-USB connector complying with the CEA-936-A standard and output a stereo sound from the left and right speakers of the head set, the left and right speakers are connected to two audio input and output pins.

From the state in which the head set outputs the stereo sound from the left and right speakers, in order to use the microphone, the microphone is connected to any one of the two audio input and output pins. In this state, the left and right speakers are connected to the other audio input and output pin, or one of the left and right speakers is connected to the other audio input and output pin.

In order to achieve switching of the aforementioned connection states in the conventional device having the micro-USB connector complying with the CEA-936-A standard, a universal asynchronous receiver transmitter (UART) chip is arranged in the head set. The connection states are switched by superimposing a command output from the UART chip on an audio signal and executing communication between the terminal device and the head set.

In the state in which the head set is connected to the conventional device having the micro-USB connector complying with the CEA-936-A standard, the head set includes the UART chip and a communication function in order to switch between the audio input and output state in which the microphone is used and the audio output state in which the microphone is not used.

A device that does not have a micro-USB connector complying with the CEA-936-A standard causes the same problem when at least one of the left and right speakers is connected to one of audio input and output terminals and the microphone is connected to the other audio input and output terminal.

The following is reference document:
[Document 1] Japanese Laid-open Patent Publication No. 2007-180742.

### SUMMARY

According to an aspect of the invention, a connector device includes: a pin; a detector coupled to the pin and detects a voltage of the pin; a controller coupled to the detector and identifies that an external device is coupled to the connector on the basis of the voltage of the pin; and a switching circuit coupled to the pin and switches an output signal on the basis of a control signal output from the controller.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a mobile phone terminal include a connector device according to a first embodiment;

FIG. 2 is a diagram illustrating the connector device according to the first embodiment;

FIG. 3 is an equivalent diagram illustrating a connection state of the connector device according to the first embodiment when the connector device according to the first embodiment is in an audio output state;

FIG. 4 is an equivalent diagram illustrating a connection state of the connector device according to the first embodiment when the connector device according to the first embodiment is in an audio input and output state;

FIG. 5 is a flowchart of a process of switching between the audio output state and audio input and output state of the connector device according to the first embodiment;

FIG. 6 is a diagram illustrating a connector device according to a second embodiment;

FIG. 7 is an equivalent diagram illustrating a connection state of the connector device according to the second embodiment when the connector device according to the second embodiment is in the audio output state;

FIG. 8 is an equivalent diagram illustrating a connection state of the connector device according to the second embodiment when the connector device according to the second embodiment is in the audio input and output state;

FIG. 9 is a diagram illustrating a connector device according to a third embodiment;

FIG. 10 is an equivalent diagram illustrating a connection state of the connector device according to the third embodiment when the connector device according to the third embodiment is in the audio output state; and

FIG. 11 is an equivalent diagram illustrating a connection state of the connector device according to the third embodiment when the connector device according to the third embodiment is in the audio input and output state.

### DESCRIPTION OF EMBODIMENTS

Hereinafter, embodiments of a connector device and electronic device that are disclosed herein are described.

### First Embodiment

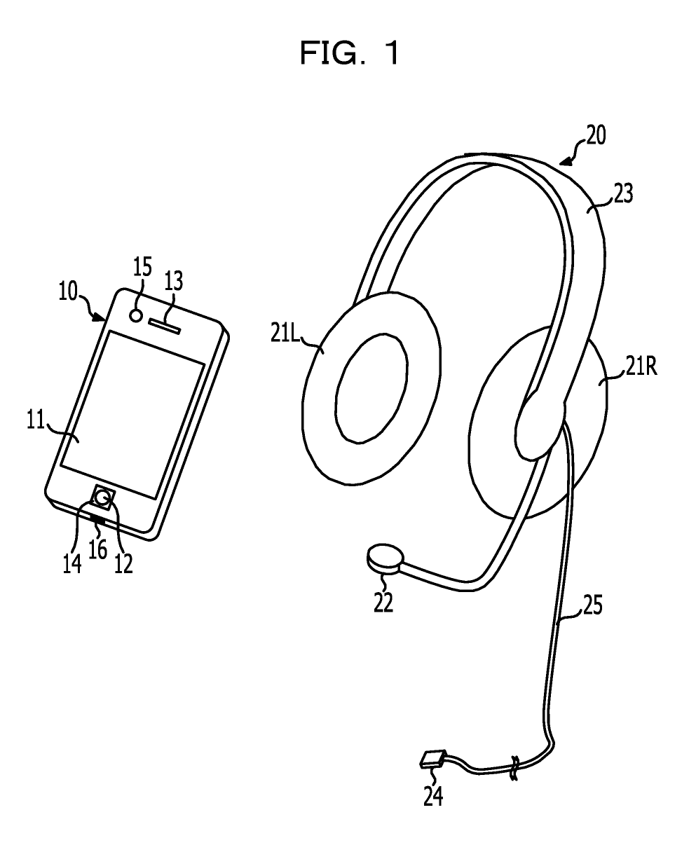

FIG. 1 is a perspective view of a smart phone 10 and a head set 20 that include a connector device 100 according to the first embodiment.

The smart phone terminal 10 that includes a part of the connector device 100 according to the first embodiment includes a touch panel 11, an operation button 12, a speaker 13 for calls, a microphone 14 for calls, a digital camera 15 and a micro-USB connector 16. The touch panel 11 is arranged on the side of a front surface of the smart phone terminal 10.

The smart phone terminal 10 may include an additional device that is a near field communication device (infrared communication device, communication device for electronic money or the like).

The micro-USB connector 16 may be connected to the head set 20. The head set 20 is an example of an external device and includes left and right speakers 21L and 21R, a microphone 22, a frame 23, a micro-USB connector 24 and a cable 25.

When the micro-USB connector 24 that is connected to an end of the cable 25 is connected to the micro-USB connector 16 of the smart phone terminal 10, the head set 20 may output a stereo sound from the speakers 21L and 21R. In this case, the speakers 21L and 21R are connected to two audio inputs and output pins among five pins of the micro-USB connector 24 and are thereby connected to two audio input and output pins among five pins of the micro-USB connector 16.

When the stereo sound is output from the speakers 21L and 21R, and a call button that is displayed on the touch panel 11 is pressed or the smart phone terminal 10 receives a call, the speakers 21L and 21R are connected to one of the two audio input and output pins included in the micro-USB connector 24 and are thereby connected to one of the two audio input and output pins included in the micro-USB connector 16, and the microphone 22 is connected to the other of the two audio input and output pins included in the micro-USB connector 24 and is thereby connected to the other of the two audio input and output pins included in the micro-USB connector 16.

When the head set 20 is connected to the smart phone terminal 10 and the smart phone terminal 10 is in a non-calling state, the head set 20 may output a stereo sound from the speakers 21L and 21R.

When the head set 20 is connected to the smart phone terminal 10 and the smart phone terminal 10 is in a calling state, the head set 20 may output a monaural sound from the speakers 21L and 21R and a sound may be input to the microphone 22.

The calling state is a state in which a power supply of the smart phone terminal 10 is in an ON state and a call is connected by the smart phone terminal 10. The calling state may include a state in which the smart phone terminal 10 rings after receiving a call and before connecting the call. In the calling state, the head set 20 is in an audio input and output state in which the head set 20 may output a monaural sound from the speakers 21L and 21R and a sound may be input to the microphone 22.

The non-calling state is a state in which the power supply of the smart phone terminal 10 is in the ON state and the smart phone terminal 10 is not in the calling state. In the non-calling state, the head set 20 is in an audio output state in which the microphone 22 is turned off and the head set 20 outputs a stereo sound from the speakers 21L and 21R.

The connector device 100 according to the first embodiment is achieved by the micro-USB connector 16 of the smart phone terminal 10 and the micro-USB connector 24 of the head set 20.

In the state in which the smart phone terminal 10 is connected to the head set 20, the connector device 100 according to the first embodiment may easily switch between the calling state and the non-calling state.

A circuit configuration and method for switching between the calling state and the non-calling state are described below.

FIG. 1 illustrates the smart phone terminal 10 as an example of a terminal device. The terminal device, however, is not limited to the smart phone terminal 10. The terminal device may be a mobile phone terminal, a game machine or the like.

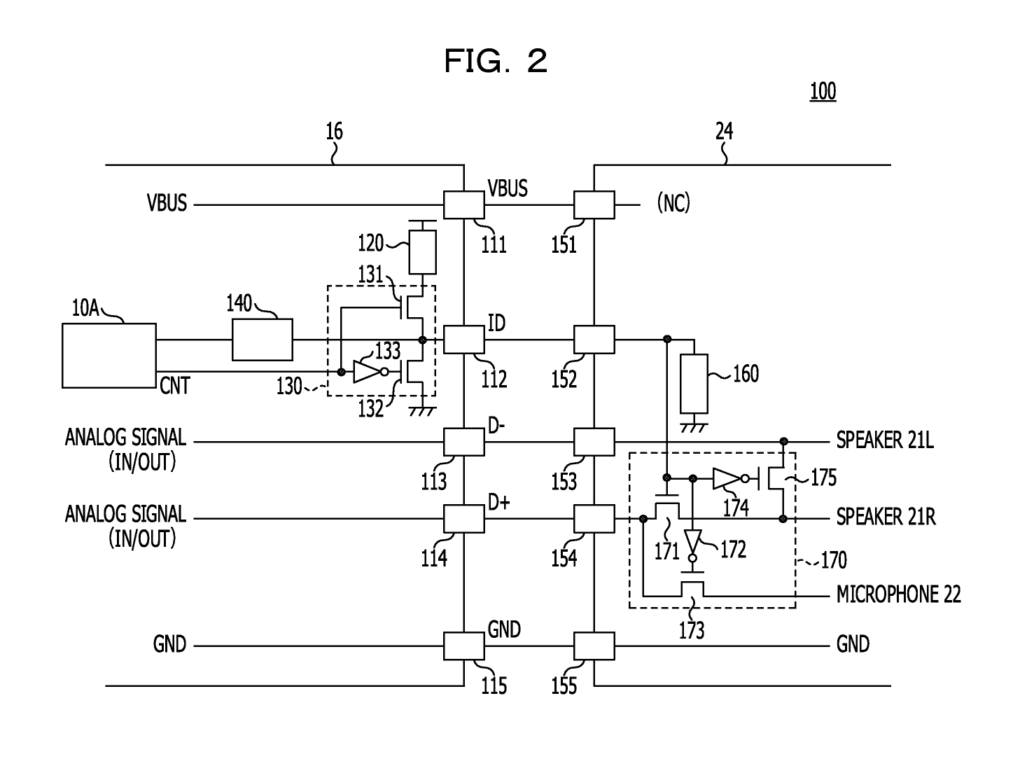

FIG. 2 is a diagram illustrating the connector device 100 according to the first embodiment.

The connector device 100 according to the first embodiment includes the micro-USB connector 16 of the smart phone terminal 10 (illustrated in FIG. 1) and the micro-USB connector 24 of the head set 20.

The micro-USB connector 16 includes pins 111 to 115, a pull-up resistor 120, an output switching circuit 130 and an ID detector 140. The output switching circuit 130 and the ID detector 140 are connected to a central processing unit (CPU) 10A of the smart phone terminal 10. The CPU 10A is an example of a controller that executes data processing related to a call of the smart phone terminal 10.

The micro-USB connector 24 includes pins 151 to 155, a pull-down resistor 160 and a connection switching circuit 170.

Although the pins 111 to 115 are disconnected from the pins 151 to 155 in FIG. 2 in order to easily understand the connector device 100, the following description assumes that the pins 111 to 115 are connected to the pins 151 to 155.

The pins 111 to 115 are the five pins included in the micro-USB connector 16. The pins 111 to 115 are connected to the pins 151 to 155, respectively.

The pin 111 is connected to the power supply (VBUS) of the smart phone terminal 10.

The pin 112 is an ID pin and connected to the ID detector 140 through a midpoint of transistors 131 and 132 of the output switching circuit 130. The pin 112 is hereinafter referred to as an ID pin 112.

The pin 113 receives and outputs an analog signal. The pin 113 is connected to one of input and output pins of an audio input and output section of the smart phone terminal 10. The pin 113 outputs an audio signal (signal indicating a call sound, a sound generated due to an operation of the smart phone terminal 10, a musical sound or the like) of the smart phone terminal 10. If the pin 113 is connected to a microphone, the pin 113 may enable a sound to be input to the smart phone terminal 10. In the first embodiment, however, the pin 113 is used as a pin that outputs a sound. An output of the pin 113 is indicated by D-.

The pin 114 receives and outputs an analog signal. The pin 114 is connected to the other of the input and output pins of the audio input and output section of the smart phone terminal 10 in the same manner as the pin 113. The pin 114 outputs an audio signal (signal indicating a call sound, a sound generated due to an operation of the smart phone terminal 10, a musical sound or the like) of the smart phone terminal 10. The pin 114 may enable a sound to be input to the smart phone terminal 10 when the pin 114 is connected to the microphone 22 of the head set 20. An output of the pin 114 is indicated by D+.

When the smart phone terminal 10 is in the non-calling state, the pins 113 and 114 are connected to the speakers 21L and 21R of the head set 20, respectively. When the smart phone terminal 10 is in the non-calling state and the pins 113 and 114 are connected to the speakers 21L and 21R, respectively, a stereo sound is output from the speakers 21L and 21R.

The pin 115 is connected to a ground (GND) pin of the smart phone terminal 10.

The pull-up resistor 120 is connected to the power supply that supplies a predetermined voltage. The pull-up resistor 120 is connected to the ID pin 112 through a main path of the transistor 131. When the pull-down resistor 160 is connected to the ID pin 112 through the pin 152, the resistance of the pull-up resistor 120 is set to a value that causes a predetermined voltage to be generated at the ID pin 112.

Specifically, when the pull-down resistor 160 is connected to the ID pin 112 through the pin 152, the voltage that is divided by the pull-up resistor 120 and the pull-down resistor 160 is generated at the ID pin 112. The generated voltage is detected by the ID detector 140 and used to identify that the head set 20 is connected to the smart phone terminal 10.

The output switching circuit 130 includes the transistors 131 and 132 and an inverter 133.

The transistor 131 is an N-type metal oxide semiconductor (NMOS) transistor, for example. A drain of the transistor 131 is connected to the pull-up resistor 120. A source of the transistor 131 is connected to a drain of the transistor 132 and the ID pin 112. A gate of the transistor 131 is connected to the CPU 10A. The transistor 131 is an example of a first output switching element.

A control signal CNT is input to the gate of the transistor 131 from the CPU 10A. If the control signal CNT is at a high (H) level, the transistor 131 is turned on. If the control signal CNT is at a low (L) level, the transistor 131 is turned off.

The transistor 132 is an NMOS transistor, for example. The drain of the transistor 132 is connected to the source of the transistor 131 and the ID pin 112. A source of the transistor 132 is grounded. A gate of the transistor 132 is connected to the CPU 10A through the inverter 133. The main path of the transistor 131 extends between the drain and source of the transistor 131, while a main path of the transistor 132 extends between the drain and source of the transistor 132. The main paths of the transistors 131 and 132 are connected to each other between the pull-up resistor 120 and the ground. The transistor 132 is an example of a second output switching element.

The level of the control signal CNT that is output from the CPU 10A is inverted by the inverter 133. The inverted control signal CNT is input to the gate of the transistor 132. If the control signal CNT is at the high (H) level, the transistor 132 is turned off. If the control signal CNT is at the low (L) level, the transistor 132 is turned on. Thus, when the transistor 131 is turned on, the transistor 132 is turned off. When the transistor 131 is turned off, the transistor 132 is turned on.

If the control signal CNT is at the H level, the transistor 131 is turned on, the transistor 132 is turned off and the voltage for the identification is generated at the ID pin 112. If the control signal at the L level, the transistor 131 is turned off, the transistor 132 is turned on and the ID pin 112 is maintained at a ground potential.

The ID detector 140 is an example of a detector that detects a potential of the ID pin 112. As the ID detector 140, a comparator or an analog-to-digital converter may be used.

An input terminal of the ID detector 140 is connected to the ID pin 112 through the midpoint of the transistors 131 and 132 of the output switching circuit 130. An output terminal of the ID detector 140 is connected to the CPU 10A.

The ID detector 140 detects the voltage generated at the ID pin 112. As described above, when the pull-down resistor 160 is connected to the ID pin 112 through the pin 152, the voltage that is divided by the pull-up resistor 120 and the pull-down resistor 160 is generated at the ID pin 112. The generated voltage is detected by the ID detector 140 and used to identify that the head set 20 is connected to the smart phone terminal 10.

A signal that indicates the voltage detected by the ID detector 140 is input to the CPU 10A.

The pin 151 is connected to the pin 111 and receives supplied power. The head set 20 according to the first embodiment does not receive power from the smart phone terminal 10. Thus, the pin 151 is not actually used and not connected in the micro-USB connector 24. Thus, an output of the pin 151 is indicated by NC (non-connection).

The pin 152 is connected to the ID pin 112. The pin 152 is connected to the pull-down resistor 160 and a gate of a transistor 171 included in the connection switching circuit 170.

The pin 153 is connected to the left speaker 21L of the head set 20 and a source of a transistor 175 included in the connection switching circuit 170.

The pin 154 is connected to a drain of the transistor 171 and a drain of a transistor 173 included in the connection switching circuit 170.

The pin 155 is connected to a ground (GND) line that is maintained at the ground potential.

One (terminal illustrated on the upper side of FIG. 2) of terminals of the pull-down resistor 160 is connected to the pin 152, the gate of the transistor 171 of the connection switching circuit 170 and input terminals of inverters 172 and 174, while the other (terminal illustrated on the lower side of FIG. 2) of the terminals of the pull-down resistor 160 is grounded.

The resistance of the pull-down resistor 160 is set to 100 kΩ according to the CEA-936-A standard.

The connection switching circuit 170 includes the transistor 171, the inverter 172, the transistor 173, the inverter 174 and the transistor 175.

The transistor 171 is an NMOS transistor, for example. The drain of the transistor 171 is connected to the pin 154. A source of the transistor 171 is connected to the speaker 21R (refer to FIG. 1). The gate of the transistor 171 is connected to the pin 152. The transistor 171 is an example of a first connection switching element.

An input terminal of the inverter 172 is connected to the pin 152, while an output terminal of the inverter 172 is connected to a gate of the transistor 173.

The drain of the transistor 173 is connected to the pin 154. A source of the transistor 173 is connected to the microphone 22 (refer to FIG. 1). The gate of the transistor 173 is connected to the output terminal of the inverter 172. The transistor 173 is an example of a second connection switching element.

An input terminal of the inverter 174 is connected to the pin 152, while an output terminal of the inverter 174 is connected to a gate of the transistor 175.

A drain of the transistor 175 is connected to the source of the transistor 171 and the speaker 21R (refer to FIG. 1). The source of the transistor 175 is connected to the pin 153 and the speaker 21L (refer to FIG. 1). The gate of the transistor 175 is connected to the output terminal of the inverter 174. The transistor 175 is an example of a third connection switching element.

If the control signal CNT is at the H level and the voltage for the identification is input to the pin 152 from the ID pin 112, the transistor 171 of the connection switching circuit 170 is turned on and the transistors 173 and 175 of the connection switching circuit 170 are turned off. Thus, the pull-down resistor 160 is connected to the pin 152.

If the control signal CNT is at the L level and the terminal 152 is grounded through the ID pin 112, the transistor 171 is turned off and the transistors 173 and 175 are turned on. Thus, the speakers 21L and 21R are connected to the pin 153, and the microphone 22 is connected to the pin 154.

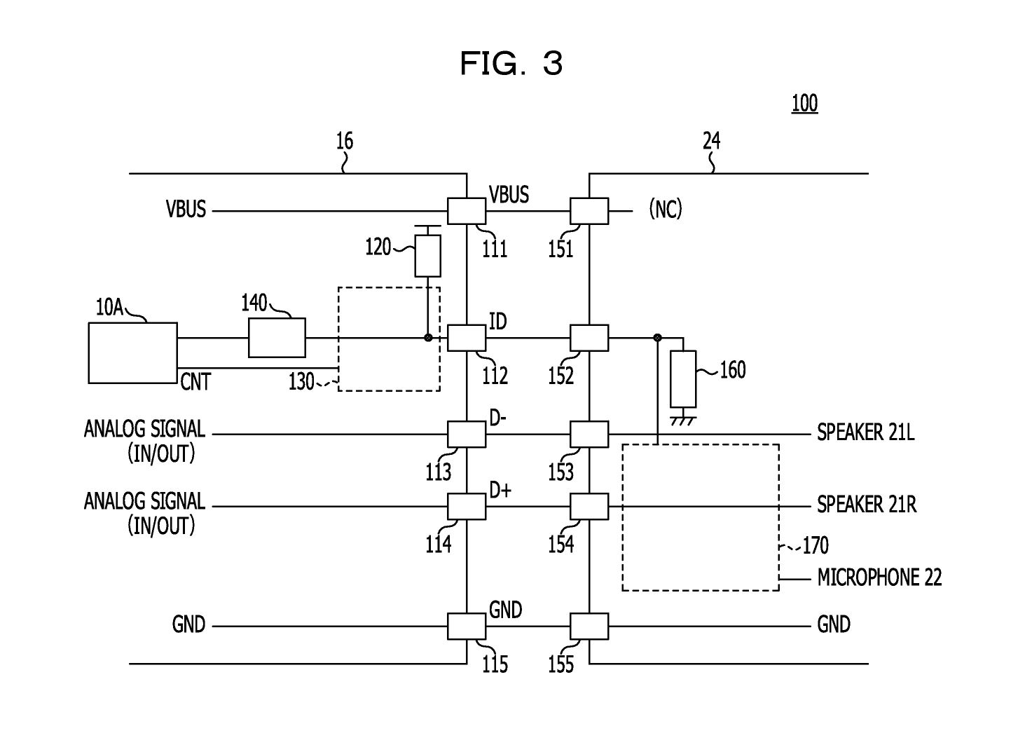

The connector device 100 according to the first embodiment switches between the audio output state and the audio input and output state by switching the states of the output switching circuit 130 and connection switching circuit 170. The audio output state and the audio input and output state are described below with reference to FIGS. 2 and 3.

FIG. 3 is an equivalent diagram illustrating a connection state of the connector device 100 according to the first embodiment when the connector device 100 is in the audio output state.

In order for the connector device 100 to become the audio output state, the control signal CNT is set to the H level. When the control signal CNT is set to the H level, the transistor 131 is turned on and the transistor 132 is turned off. Thus, the output switching circuit 130 connects the pull-up resistor 120 and the ID detector 140 to the ID pin 112 as illustrated in FIG. 3.

In this case, the pull-down resistor 160 is connected to the ID pin 112 through the pin 152. Thus, the voltage for the identification is generated at the pin 152, and the connection switching circuit 170 connects the pin 154 to the speaker 21R.

If the micro-USB connector 16 and 24 are connected to each other and the control signal CNT is at the H level, the speaker 21L is connected to the one of the input and output pins of the audio input and output section of the smart phone terminal 10 through the pins 153 and 113. In this case, the speaker 21R is connected to the other of the input and output pins of the audio input and output section through the pins 154 and 114.

If the micro-USB connector 16 and 24 are connected to each other and the control signal CNT is at the H level, the head set 20 may output a stereo sound from the speakers 21L and 21R.

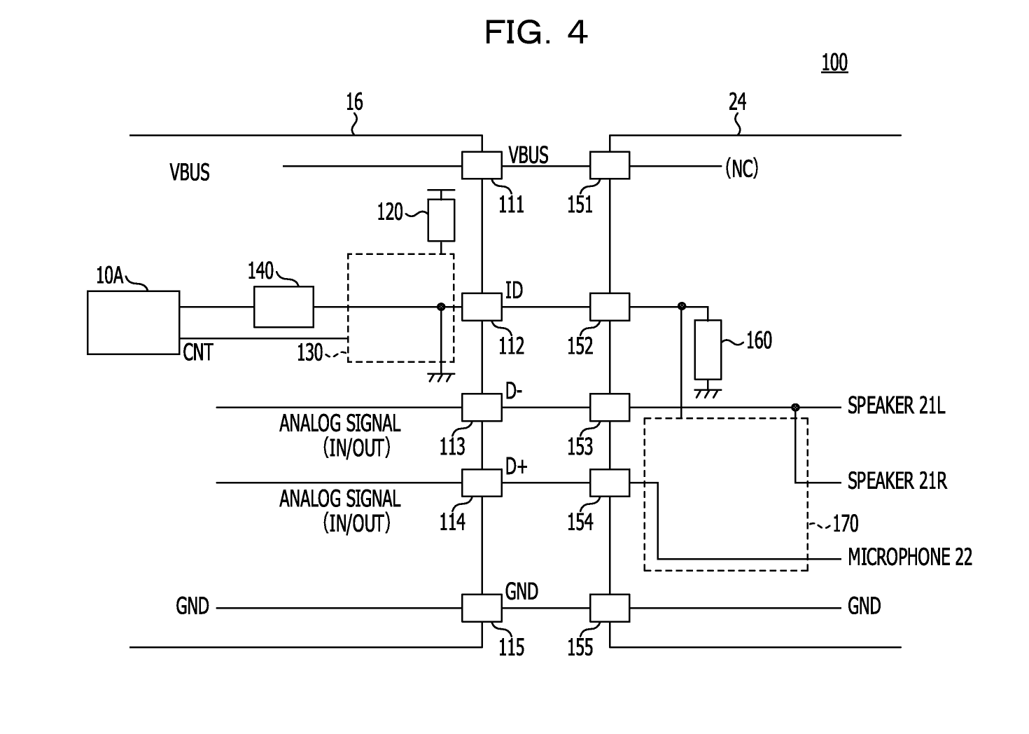

FIG. 4 is an equivalent diagram illustrating a connection state of the connector device 100 according to the first embodiment when the connector device 100 is in the audio input and output state.

In order for the connector device 100 to become the audio input and output state, the control signal CNT is set to the L level. When the control signal CNT is set to the L level, the transistor 131 is turned off and the transistor 132 is turned on. Thus, the output switching circuit 130 causes the ID pin 112 and the input terminal of the ID detector 140 to be grounded.

In this case, the pin 152 is grounded through the pin 112. Thus, the connection switching circuit 170 connects the pin 153 to the speakers 21L and 21R and connects the pin 154 to the microphone 22.

If the micro-USB connector 16 and 24 are connected to each other and the control signal CNT is at the L level, the speakers 21L and 21R are connected to the one of the input and output terminals of the audio input and output section of the smart phone terminal 10 through the pins 153 and 113. In this case, the microphone 22 is connected to the other of the input and output terminals of the audio input and output section through the pins 154 and 114.

Thus, if the micro-USB connector 16 and 24 are connected to each other and the control signal CNT is at the L level, the head set 20 may output a monaural sound from the speakers 21L and 21R, and a sound input to the microphone 22 may be input to the other of the input and output terminals of the audio input and output section of the smart phone terminal 10.

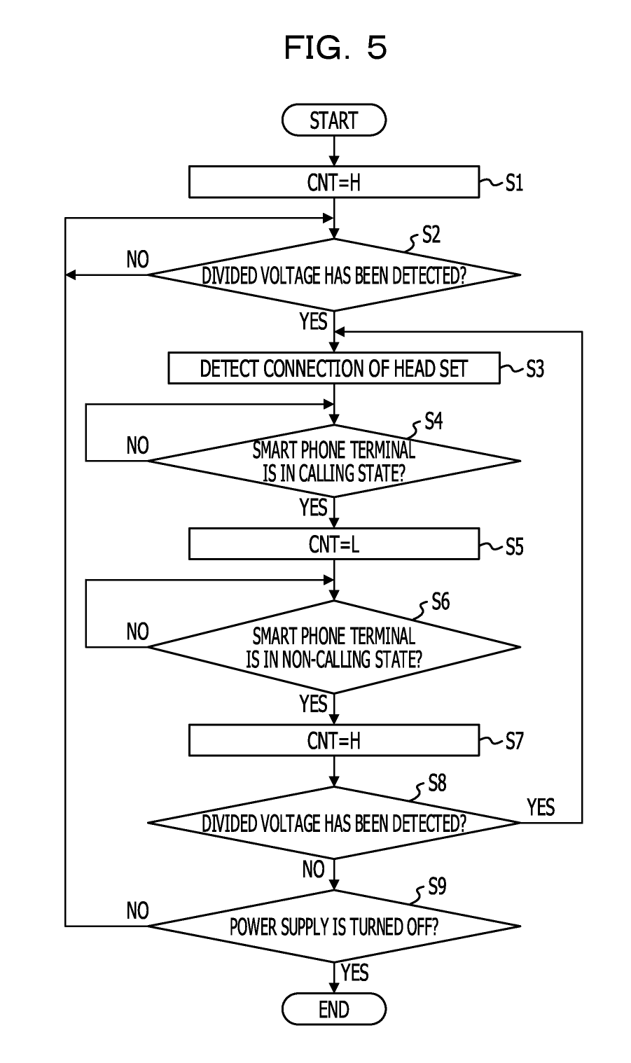

Next, a process of switching between the audio output state and audio input and output state of the connector device 100 according to the first embodiment is described with reference to a flowchart of FIG. 5.

FIG. 5 is the flowchart of the process of switching between the audio output state and audio input and output state of the connector device 100 according to the first embodiment. The process illustrated in FIG. 5 is executed by the CPU 10A of the smart phone terminal 10.

When the power supply of the smart phone terminal 10 is turned on, the CPU 10A sets the control signal CNT to the H level (in step S1).

Next, the CPU 10A determines whether or not the ID detector 140 has detected the divided voltage (in step S2). The divided voltage is generated at the ID pin 112 by connecting the pull-down resistor 160 to the ID pin 112 through the pin 152 when the control signal CNT is at the H level.

If the ID detector 140 has detected the divided voltage in step S2, the CPU 10A detects that the head set 20 is connected to the smart phone terminal 10 (in step S3). If the ID detector 140 has not detected the divided voltage in step S2, the head set 20 is not connected to the smart phone terminal 10 and the CPU 10A repeats the process of step S2.

Next, the CPU 10A determines whether or not the smart phone terminal 10 is in the calling state (in step S4). in order to change the head set 20 to the audio input and output state when the smart phone terminal 10 is in the calling state, the CPU 10A makes the determination in step S4.

The CPU 10A executes data processing related to calls. Thus, whether or not the smart phone terminal 10 is in the calling state is determined by determining whether or not a call button is pressed and a call is placed or determining whether or not a call is received, an answer button is pressed and the call is connected.

If the CPU 10A determines that the smart phone terminal 10 is in the calling state in step S4, the CPU 10A sets the control signal CNT to the L level (in step S5). In this case, the CPU 10A sets the control signal CNT to the L level in order to change the head set 20 to the audio input and output state, connect the speakers 21L and 21R to the one of the input and output terminals of the audio input and output section of the CPU 10A and connect the microphone 22 to the other of the input and output terminals.

Next, the CPU 10A determines whether or not the smart phone terminal 10 is in the non-calling state (in step S6). If the call is terminated and the smart phone terminal 10 becomes the non-calling state, the head set 20 is changed to the audio output state.

The CPU 10A determines whether or not an end call button has been pressed and thereby determines whether or not the smart phone terminal 10A is in the non-calling state.

If the CPU 10A determines that the smart phone terminal 10 is in the non-calling state in step S6, the CPU 10A sets the control signal CNT to the H level (in step S7). Thus, the speakers 21L and 21R of the head set 20 are connected to the two input and output terminals of the audio input and output section of the CPU 10A, respectively.

Next, the CPU 10A determines whether or not the ID detector 140 has detected the divided voltage (in step S8). The CPU 10A makes the determination in step S8 in order to determine whether or not the head set 20 continues to be connected.

If the CPU 10A determines that the ID detector 140 has detected the divided voltage in step S8, the CPU 10A causes the process to return to step S3. Then, the CPU 10A detects the connection of the head set 20 (in step S3) and then determines whether or not the smart phone terminal 10 is in the calling state (in step S4).

If the CPU 10A determines that the ID detector 140 has not detected the divided voltage in step S8, the CPU 10A determines whether or not the power supply of the smart phone terminal 10 has been turned off (in step S9). In order not to change the level of the control signal CNT when the power supply of the smart phone terminal 10 has been turned off, the CPU 10A makes the determination in step S9.

If the CPU 10A determines that the power supply has not been turned off in step S9, the CPU 10A causes the process to return to step S2 and determines whether or not the ID detector 140 has detected the divided voltage (in step S2) in order to determine whether or not the head set 20 has been connected again.

If the CPU 10A determines that the power supply has been turned off in step S9, the CPU 10A terminates the process.

As described above, regarding the connector device 100 according to the first embodiment, the head set 20 may be easily changed from the audio output state to the audio input and output state by changing the level of the control signal CNT that is output from the CPU 10A of the smart phone terminal 10.

The head set 20 does not use a UART chip unlike conventional techniques. With a simple configuration that does not include a communication function; the head set 20 may be changed from the audio output state to the audio input and output state. Since the head set 20 does not have a communication function, the head set 20 does not consume power unlike a head set having a UART chip and contributes to an increase in a continuous operating time of the smart phone terminal 10.

Unlike a head set having a conventional UART chip, a command is not superimposed on an audio signal. Thus, an audio signal does not include noise and the like.

For a conventional mobile phone terminal (such as a smart phone or a mobile terminal) in which a micro-USB connector is used, a connector that has 10 pins and complies with the ARIB standard has been used. Since phone terminals have been downsized, small micro-USB connectors that each have 5 pins increasingly tends to be used for phone terminals.

Since the micro-USB connectors are small, the micro-USB connectors largely contribute to reductions in the sizes and thicknesses of the phone terminals. Since the small micro-USB connectors each have 5 pins, the use of the micro-USB connectors, however, may be limited.

Regarding the connector device 100 according to the first embodiment, even when the micro-USB connectors 16 and 24 each have the five pins, the head set 20 may be easily changed from the audio output state to the audio input and output state.

The configuration in which the connection switching circuit 170 includes the transistor 175 is described above. The connection switching circuit 170, however, may not include the transistor 175. If the connection switching circuit 170 does not include the transistor 175 and the head set 20 is in the audio input and output state, only the speaker 21L is connected to the audio input and output section of the CPU 10A, and the speaker 21R does not output a sound. Thus, a call is connected using the speaker 21L and the microphone 22.

In addition, the configuration in which the output switching circuit 130 uses the NMOS transistors as the transistors 131 and 132 is described above. The transistors 131 and 132, however, may be PMOS transistors. In this case, the levels of the control signal CNT are reversed, compared with the aforementioned case.

Furthermore, the configuration in which the output switching circuit 130 uses the inverter 133 so as to alternately use the transistors 131 and 132 is described above. The inverter 133 may not be used, and the transistor 132 may be a PMOS transistor.

The transistors 171, 173 and 175 of the connection switching circuit 170 may be PMOS transistors, and the levels of the control signal CNT may be reversed, compared with the aforementioned case.

The inverters 172 and 174 may not be used, and PMOS transistors may be used as the transistors 173 and 175.

The connector device 100 that includes the micro-USB connectors 16 and 24 is described above. The connector device 100 is not limited to the connector device that includes the micro-USB connectors 16 and 24.

Specifically, it is sufficient if the connector device 100 connects the speakers 21L and 21R and the microphone 22 to the smart phone terminal 10 in the audio output state and the audio input and output state.

### Second Embodiment

The configuration of an output switching circuit included in a connector device 200 according to the second embodiment is different from the connector device 100 according to the first embodiment. Other configurations of the connector device 200 according to the second embodiment are the same as the connector device 100 according to the first embodiment. Constituent elements of the connector device 200 according to the second embodiment, which are the same as those of the connector device 100 according to the first embodiment, are indicated by the same reference numerals and symbols as those described in the first embodiment, and a description thereof is omitted.

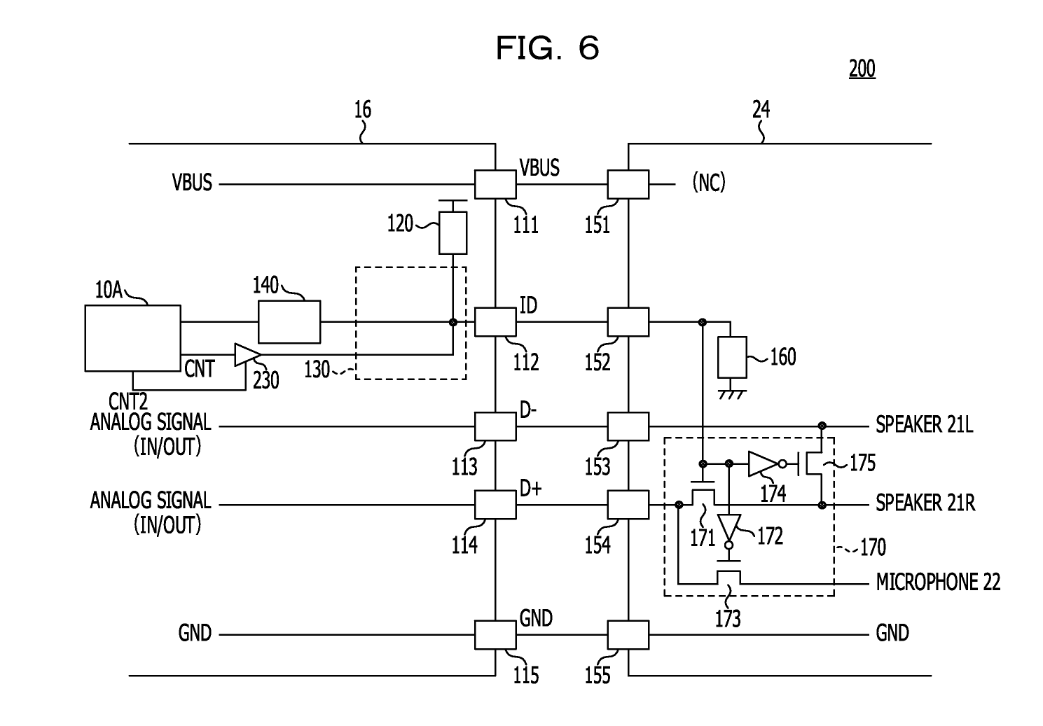

FIG. 6 is a diagram illustrating the connector device 200 according to the second embodiment.

The connector device 200 according to the second embodiment includes the micro-USB connector 16 and the micro-USB connector 24 of the head set 20, like the connector device 100 according to the first embodiment.

The micro-USB connector 16 includes the pins 111 to 115, the pull-up resistor 120, an output switching circuit 230 and the ID detector 140. The CPU 10A of the smart phone terminal 10 is connected to the output switching circuit 230 and the ID detector 140.

The ID pin 112 that is among the pins 111 to 115 is connected to the pull-up resistor 120, the output switching circuit 230 and the ID detector 140.

One (terminal illustrated on the upper side of FIG. 6) of end terminals of the pull-up resistor 120 is connected to the power supply that outputs the predetermined voltage, while the other (terminal illustrated on the lower side of FIG. 6) of the end terminals of the pull-up resistor 120 is connected to the ID pin 112, an output terminal of the output switching circuit 230 and the input terminal of the ID detector 140.

The output switching circuit 230 is a three-state buffer. An input terminal of the output switching circuit 230 is connected to the CPU 10A, while the output terminal of the output switching circuit 230 is connected to the ID pin 112. A control signal input terminal of the output switching circuit 230 is connected to the CPU 10A.

The control signal CNT is input to the input terminal of the output switching circuit 230 from the CPU 10A. A control signal CNT2 is input to the control signal input terminal from the CPU 10A. The control signal CNT is the same as the control signal CNT described in the first embodiment. The control signal CNT2 is a control signal to be used to switch an output of the three-state buffer.

If the control signal CNT2 is at a high (H) level, the output switching circuit 230 outputs the control signal CNT (input to the input terminal) without a change. If the control signal CNT2 is at a low (L) level, an output of the output switching circuit 230 is set to high impedance (Hi-Z).

When the CPU 10A sets the control signal CNT to the H level, the CPU 10A sets the control signal CNT2 to the L level. When the CPU 10A sets the control signal CNT to the L level, the CPU 10A sets the control signal CNT2 to the H level.

When the CPU 10A outputs the control signal CNT of the H level and the control signal CNT2 of the L level, the output of the output switching circuit 230 is set to the high impedance (Hi-Z), and whereby the ID pin 112 is connected to the pull-up resistor 120 and the input terminal of the ID detector 140. This state of the ID pin 112 is the same as the state (refer to FIG. 3) when the CPU 10A sets the control signal CNT to the H level in the first embodiment.

When the CPU 10A outputs the control signal CNT of the L level and the control signal CNT2 of the H level, the output switching circuit 230 outputs the control signal CNT of the L level, and whereby the ID pin 112 is grounded. This state of the ID pin 112 is the same as the state (refer to FIG. 4) when the CPU 10A sets the control signal CNT to the L level in the first embodiment.

The input terminal of the ID detector 140 is connected to the ID pin 112 and the output terminal of the output switching circuit 230.

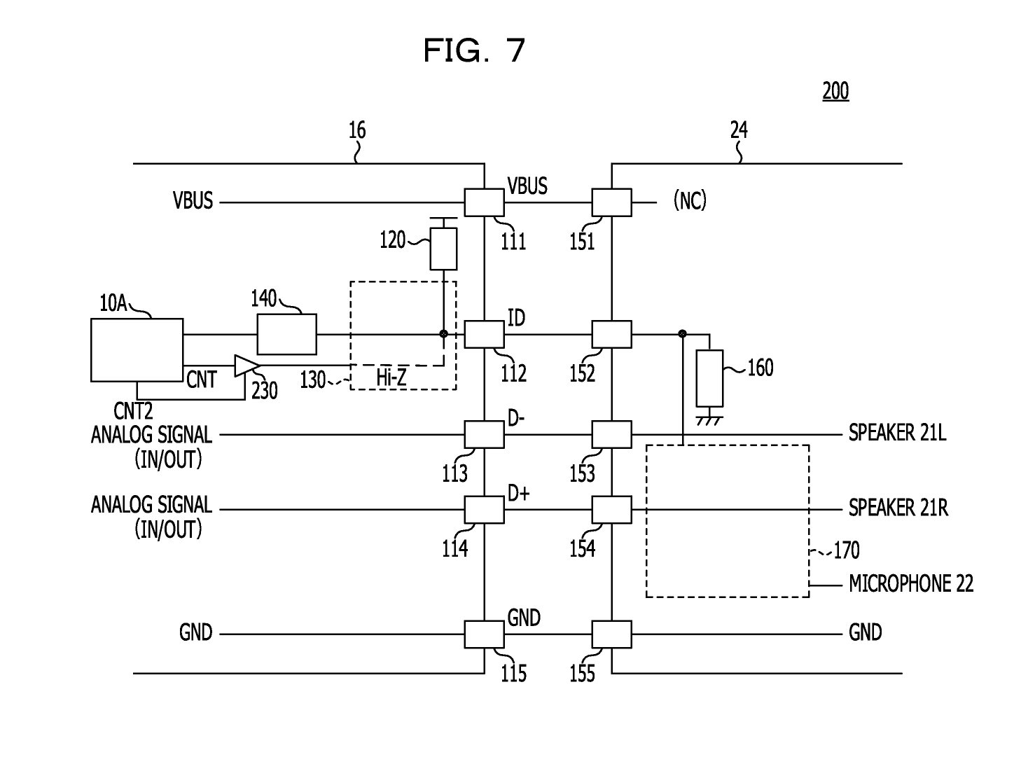

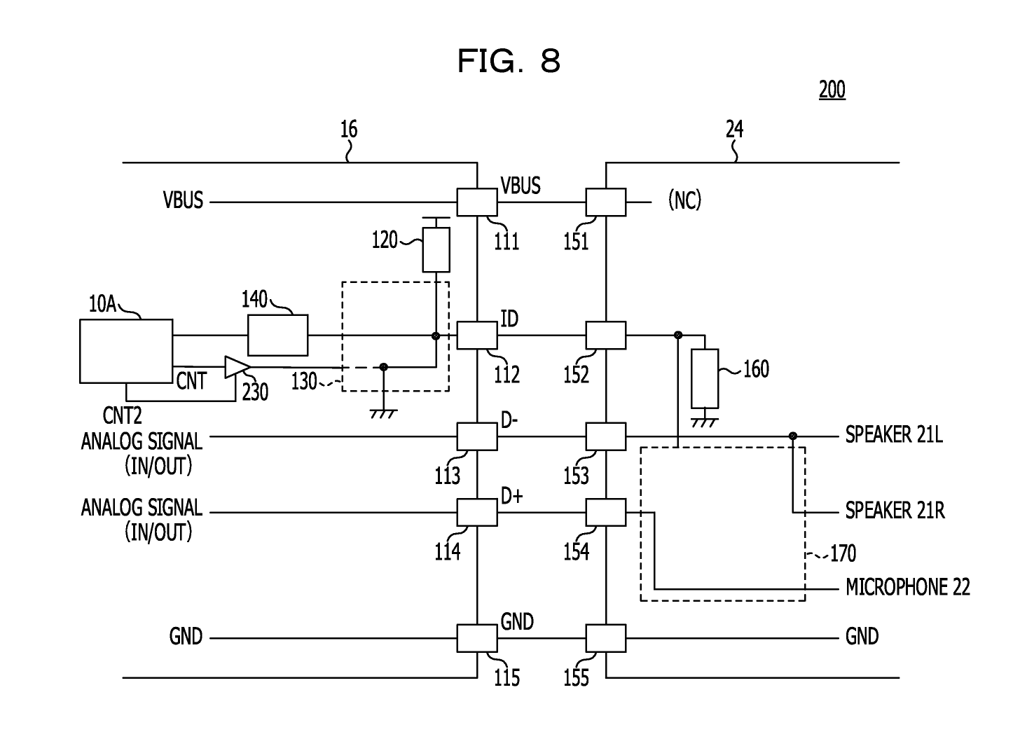

The connector device 200 according to the second embodiment switches the states of the output switching circuit 230 and connection switching circuit 170 in accordance with the control signals CNT and CNT2 and thereby switches between the audio output state and the audio input and output state. The audio output state and the audio input and output state are described below with reference to FIGS. 7 and 8.

FIG. 7 is an equivalent diagram illustrating a connection state of the connector device 200 according to the second embodiment when the connector device 200 is in the audio output state.

In order for the connector device 200 to become the audio output state, the control signal CNT is set to the H level and the control signal CNT2 is set to the L level.

Thus, the output of the output switching circuit 230 is set to the high impedance (Hi-Z), and whereby the ID pin 112 is connected to the pull-up resistor 120 and the input terminal of the ID detector 140.

In this case, the pull-down resistor 160 is connected to the ID pin 112 through the pin 152. Thus, the voltage for the identification is generated at the pin 152, and the connection switching circuit 170 connects the pin 154 to the speaker 21R.

If the micro-USB connectors 16 and 24 are connected to each other, the control signal CNT is set to the H level and the control signal CNT2 is set to the L level, the speaker 21L is connected to the one of the input and output terminals of the audio input and output section of the smart phone terminal 10 through the pins 153 and 113. In this case, the speaker 21R is connected to the other of the input and output terminals of the audio input and output section through the pins 154 and 114.

Thus, if the micro-USB connectors 16 and 24 are connected to each other, the control signal CNT is set to the H level and the control signal CNT2 is set to the L level, the head set 20 may output a stereo sound from the speakers 21L and 21R.

FIG. 8 is an equivalent diagram illustrating a connection state of the connector device 200 according to the second embodiment when the connector device 200 is in the audio input and output state.

In order for the connector device 200 to become the audio input and output state, the control signal CNT is set to the L level and the control signal CNT2 is set to the H level.

When the control signal CNT2 is set to the H level, the output of the output switching circuit 230 is set to the L level. Thus, the ID pin 112 and the input terminal of the ID detector 140 are grounded as illustrated in FIG. 8.

In this case, the pin 152 is grounded through the ID pin 112. Thus, the connection switching circuit 170 connects the pin 153 to the speakers 21L and 21R and connects the pin 154 to the microphone 22.

If the micro-USB connectors 16 and 24 are connected to each other, the control signal CNT is set to the L level and the control signal CNT2 is set to the H level, the speakers 21L and 21R are connected to the one of the input and output terminals of the audio input and output section of the smart phone terminal 10 through the pins 153 and 113. In this case, the microphone 22 is connected to the other of the input and output terminals of the audio input and output section through the pins 154 and 114.

If the micro-USB connectors 16 and 24 are connected to each other, the control signal CNT is set to the L level and the control signal CNT2 is set to the H level, the head set 20 may output a monaural sound from the speakers 21L and 21R, and a sound input to the microphone 22 may be input to the other of the input and output terminals of the audio input and output section of the smart phone terminal 10.

### Third Embodiment

The configuration of an output switching circuit of a connector device 300 according to the third embodiment is different from the connector device 100 according to the first embodiment. Other configurations are the same as the connector device 100 according to the first embodiment. Constituent elements of the connector device 300 according to the third embodiment, which are the same as those of the connector device 100 according to the first embodiment, are indicated by the same reference numerals and symbols as those described in the first embodiment, and a description thereof is omitted.

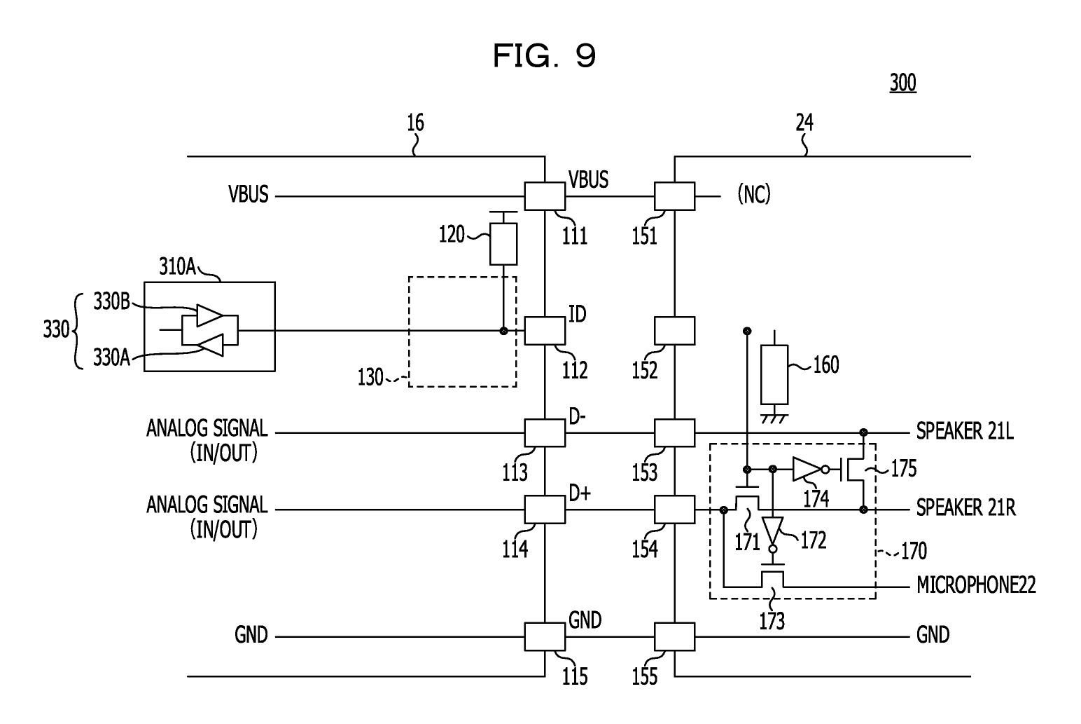

FIG. 9 is a diagram illustrating the connector device 300 according to the third embodiment.

The connector device 300 according to the third embodiment includes the micro-USB connector 16 and the micro-USB connector 24 of the head set 20, like the connector device 100 according to the first embodiment.

The micro-USB connector 16 includes the pins 111 to 115, the pull-up resistor 120 and an output switching circuit 330.

The output switching circuit 330 has a function achieved by causing a CPU 310A to execute a computer program. The CPU 310A is achieved by adding the output switching circuit 330 and the function of the ID detector 140 to the CPU 10A described in the first embodiment. The connector device 300 according to the third embodiment does not include the ID detector 140 (refer to FIG. 2). The CPU 310A detects the divided voltage.

The ID pin 112 that is among the pins 111 to 115 is connected to the pull-up resistor 120 and the output switching circuit 330 of the CPU 310A.

The one (terminal illustrated on the upper side of FIG. 9) of the end terminals of the pull-up resistor 120 is connected to the power supply that outputs the predetermined voltage, while the other (terminal illustrated on the lower side of FIG. 9) of the end terminals of the pull-up resistor 120 is connected to the ID pin 112 and the output switching circuit 330 of the CPU 310A.

The output switching circuit 330 has the function achieved by causing the CPU 310A to execute the computer program, as described above. The output switching circuit 330 includes a buffer 330A for inputting a signal and a buffer 330B for outputting a signal.

The CPU 310A uses the buffer 330A of the output switching circuit 330 to detect the voltage generated at the ID pin 112 in the audio output state. When the buffer 330A is used, the ID pin 112 is connected to the pull-up resistor 120. This state of the ID pin 112 is the same as the state (refer to FIG. 3) when the CPU 10A sets the control signal CNT to the H level in the first embodiment.

In this state, the CPU 310A detects the divided voltage generated at the ID pin 112. This function is the same as the function of the ID detector 140 described in the first embodiment.

The CPU 310A uses the buffer 330B of the output switching circuit 330 to maintain the ID pin 112 at the ground potential in the audio input and output state.

This state of the ID pin 112 is the same as the state (refer to FIG. 4) when the CPU 10A sets the control signal CNT to the L level in the first embodiment.

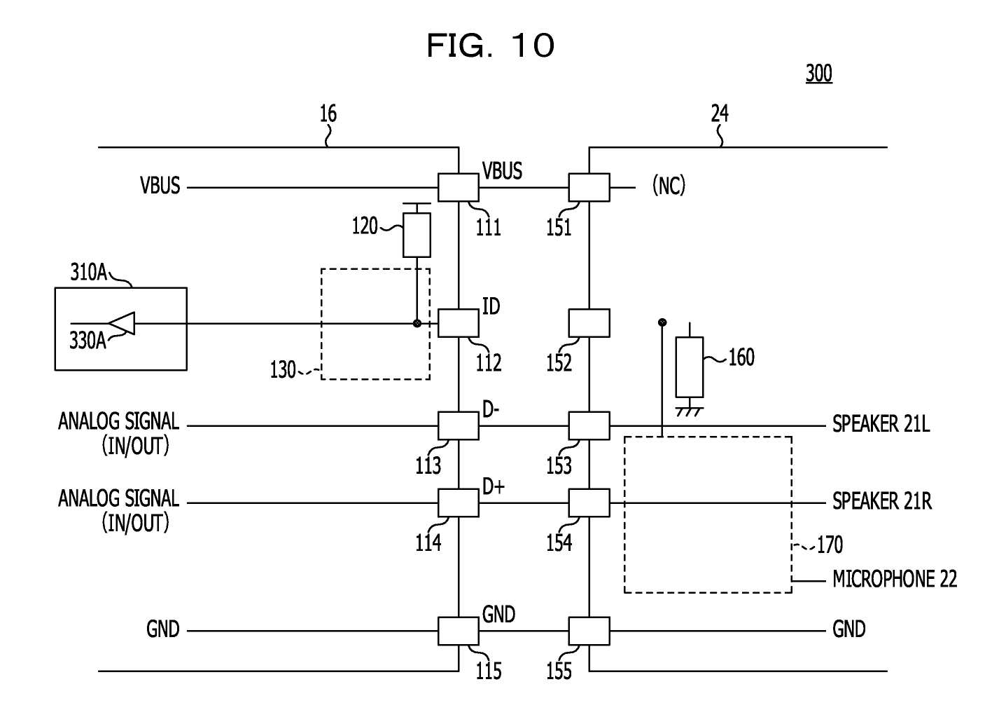

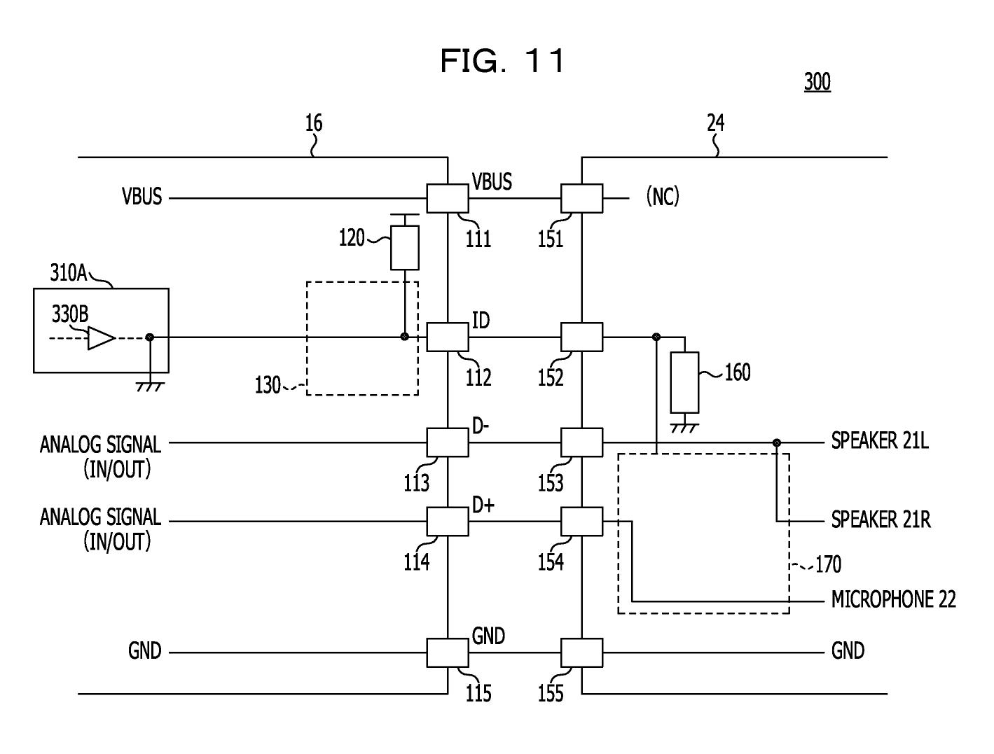

The connector device 300 according to the third embodiment switches between the buffers 330A and 330B of the output switching circuit 330 of the CPU 310A and thereby switches between the audio output state and the audio input and output state. The audio output state and the audio input and output state are described below with reference to FIGS. 10 and 11.

FIG. 10 is an equivalent diagram illustrating a connection state of the connector device 300 according to the third embodiment when the connector device 300 is in the audio output state.

In order for the connector device 300 to become the audio output state, the CPU 310A uses the buffer 330A. Thus, the pull-up resistor 120 is connected to the ID pin 112.

In this case, the pull-down resistor 160 is connected to the ID pin 112 through the pin 152. Thus, the voltage for the identification is generated at the pin 152, and the connection switching circuit 170 connects the pin 154 to the speaker 21R.

If the micro-USB connectors 16 and 24 are connected to each other and the CPU 310A uses the buffer 330A, the speaker 21L is connected to the one of the input and output terminals of the audio input and output section of the smart phone terminal 10 through the pins 153 and 113. In this case, the speaker 21R is connected to the other of the input and output terminals of the audio input and output section through the pins 154 and 114.

If the micro-USB connectors 16 and 24 are connected to each other and the CPU 310A uses the buffer 330A, the head set 20 may output a stereo sound from the speakers 21L and 21R.

FIG. 11 is an equivalent diagram illustrating a connection state of the connector device 300 according to the third embodiment when the connector device 300 is in the audio input and output state.

In order for the connector device 300 to become the audio input and output state, the CPU 310A uses the buffer 330B to maintain the ID pin 112 at the ground potential. FIG. 11 illustrates a state in which an output of the buffer 330B is connected to the GND potential. This state is achieved by causing the buffer 330B to output an L-level signal. It is sufficient if the L level signal enables the potential of the ID pin 112 to be set to a different potential from a potential for the identification, the transistor 171 of the connection switching circuit 170 to be turned on, and the transistors 173 and 175 to be turned off. It is preferable that the L-level signal be a signal of the ground potential.

When the CPU 310A uses the buffer 330B and maintains the ID pin 112 at the ground potential, the ID pin 112 is grounded as illustrated in FIG. 11.

In this case, the pin 152 is grounded through the ID pin 112, and the connection switching circuit 170 connects the pin 153 to the speakers 21L and 21R and connects the pin 154 to the microphone 22.

When the CPU 310A uses the buffer 330B and maintains the ID pin 112 at the ground potential, the speakers 21L and 21R are connected to the one of the input and output terminals of the audio input and output section of the smart phone terminal 10 through the pins 153 and 113. In this case, the microphone 22 is connected to the other of the input and output terminals of the audio input and output section through the pins 154 and 114.

When the CPU 310A uses the buffer 330B and maintains the ID pin 112 at the ground potential, the head set 20 may output a monaural sound from the speakers 21L and 21R, and a sound input to the microphone 22 may be input to the other of the input and output terminals of the audio input and output section of the smart phone terminal 10.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A connector device comprising:
a pin;
a detector coupled to the pin and detects a voltage of the pin;
a controller coupled to the detector and identifies that an external device is coupled to the pin on the basis of the voltage of the pin; and
a switching circuit coupled to the pin and switches an output signal on the basis of a control signal output from the controller.

2. The connector device according to claim 1, wherein
the output switching circuit includes
a first output switching element that is coupled to a pull-up resistor and the pin and arranged between the pull-up resistor and the pin, and
a second output switching element that is coupled to a standard potential point maintained at a predetermined standard potential and the pin and is arranged between the standard potential point and the pin,
wherein when the control signal is in the first state, the output switching circuit turns on the first switching element, turns off the second output switching element, and thereby sets the output signal to the first potential, and
wherein when the control signal is in the second state, the output switching circuit turns off the first output switching element, turns on the second output switching element, and thereby switches the output signal to the second potential.

3. The connector device according to claim 2, further comprising;
a three-state buffer that has an output terminal coupled to the first and second output switching elements,
wherein
the controller outputs a second control signal,
when the second control signal is in a third state, the three-state buffer sets the output signal to high impedance and thereby sets the output signal to the first potential, and
when the second control signal is in a fourth state, the three-state buffer maintains the first control signal output to the output switching circuit and thereby switches the output signal on the basis of a first control signal.

4. The connector device according to claim 1, wherein
the output switching circuit includes a pull-up resistor coupled to the identification pin, and
the controller that has an output terminal coupled to the identification pin,
wherein when the control signal is in the first state, the controller sets the output terminal to high impedance and thereby sets the output of the identification pin to the first potential, and
wherein when the control signal is in the second state, the controller maintains the identification pin at the second potential and thereby switches the output of the identification pin to the second potential.

5. A connector device comprising:
first and second data terminals;
first and second data lines that are coupled to the second data terminal;
an identification pin that couples an identification resistor; and
a connection switching circuit that couples any of the first and second data lines to the second data terminal on the basis of the level of a signal of the identification pin.

6. An electronic device comprising
a terminal device and an external device that are coupled to each other by a connector device,
wherein the connector device includes
a pin;
a detector coupled to the pin and identifies that an external device is coupled to the pin;
a switching circuit coupled to the pin and switches an output signal on the basis of a control signal output from a controller;
first and second data terminals;
first and second data lines that are coupled to the second data terminal;
an identification pin that couples an identification resistor; and
a connection switching circuit that couples any of the first and second data lines to the second data terminal on the basis of the level of a signal of the identification pin.
